(19) United States
(12) Patent Application Publication
(10) Pub. No.: US 2004/0131196 A1
(43) Pub. Date: Jul. 8, 2004

(54) Sound processing

(76) Inventor: David George Malham, York (GB)

Correspondence Address: William M Lee Jr, Barnes & Thornburg, PO Box 2786, Chicago, IL, 60690-2786, US

(21) Appl. No.: 10/475,282

(22) PCT Filed: Apr. 18, 2002
(86) PCT No.: PCT/GB02/01719

(30) Foreign Application Priority Data
Apr. 18, 2001 (GB) 0109498.6

(51) Int. Cl. H03G 3/00; H04R 29/00

(52) U.S. Cl. 381/61; 381/56

(57) ABSTRACT

The spatial radiation characteristics of a sounding object are encoded by spherical harmonics. The shape is decomposed (105) into a weighted sum of spherical harmonics, comprising at least the order 0 components and such higher orders as are deemed necessary. The weights are stored individually. Each shape as defined by the individual spherical harmonics is also used to calculate an impulse response for that spherical harmonic (106). These impulse responses are of a modified form where the impulse consists of sums of equally weighted components, so each time point can only take integer values for the size of the impulse at that point. The modified impulse responses are transformed into spherical harmonic form (107), after which the apparent orientation and distance of the sounding object may be varied. Any sound may be processed by using the impulse response so generated (111).

This invention relates to sound processing and is concerned particularly although not exclusively with methods and processors for encoding radiation characteristics of sounding bodies.

Systems for recording and reproducing sounds capable of retaining the spatial characteristics of an original soundfield have been known for many years. For instance, the ambisonic surround sound system uses spherical harmonics to encode the direction of sound sources win a three dimensional soundfield. Recently, this form of representation of a soundfield has been extended from the original, four channel, first order version to include second and possible higher order spherical harmonics necessary to attain higher precision and a wider useful audience area. However, even first order, four channel soundfields, recorded from real acoustic scenes using a suitable microphone, capture well the complex extended nature of real sound radiating bodies. On the other hand, even within ambisonic systems, when soundfields have to be synthesised, for instance, when constructing an artificial sound image for a film soundtrack or a computer game, the ability to portray sound sources as extended objects has been limited by available technology. As a result, this portrayal has largely been limited to either idealised point sources or to sources having a very simplified impression of being “larger than a point source”. Typically, this enlargement has, in ambisonic systems, been implemented either by simply exaggerating the non-directional zeroeth order spherical harmonic or by phase shifted based ‘spreader’ controls. In some other systems, for instance Microsoft's DirectSound, the sound source is given a limited directional variability, for instance, having a cone of directions where the sound changes character so as to appear to be facing towards or away from the listener's position. These forms of sounding body synthesis are very limited in their ability to provide realistic sound images especially as, in general, there is little or no provision for the effects of source-listener distance. Proper modelling of radiation characteristics over the whole surface is also important when generating the early reflections for a reverberation unit, since the reflections will, in most cases, not be of the part of the sounding object facing the listener.

On the other hand, it should be noted that within full acoustic simulation systems, the contributions of sounds arriving at the listening position from all points on a sounding object can be calculated by solving the wave equations for each source-listener path or by other suitable means, and this can provide fully realistic sound images. This approach, however, imposes heavy computational loadings on systems, which can be inconvenient when there is restricted available computing power or when realtime operation is desired.

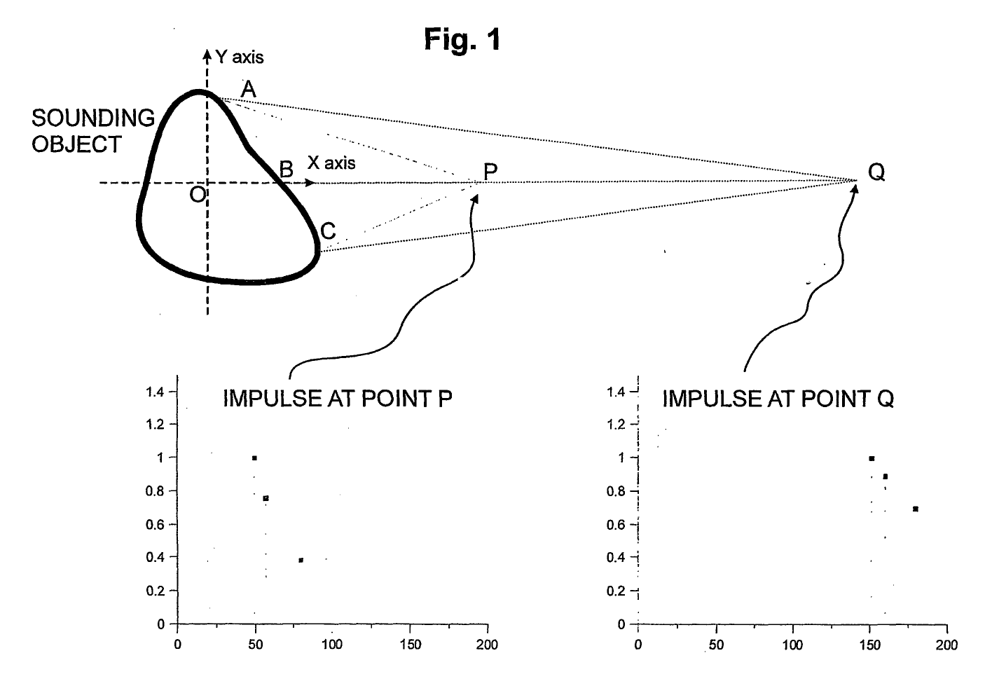

Some improvement may be made by means of a simplified model of the radiation pattern of the object. This may be coded using spherical harmonics in a manner analogous to the coding of soundfields. This allows the object to be rotated so that it maybe oriented correctly to the listening position, but it does not allow the effects of variation of the sound at the listening position with distance to be simulated appropriately. Tis variation is due to changes in the impulse response at the listener's position The impulse response changes with differing distances in two ways. Tis is illustrated in FIG. 1 of the accompanying drawings, which shows impulse responses at points spaced from a sounding object.

In FIG. 1, the impulse response is, for simplicity, shown as being provided by three points, A, B and C on the sounding object (although in reality all points on the surface would contribute) and for two listener positions, P and Q. Both the position of the impulses in time and the differences in their amplitudes change with distance. Note that, as the distance increases between the object and the listener, the extra distance contribution of the displacement away from the origin along the Y axis decreases leading eventually; in the far field, to the situation where only distances along the X axis count.

Preferred embodiments of the present invention aim to provide systems in which further characteristics of a sounding body are encoded using spherical harmonics in such a way as to allow simulation of both the radiation pattern of the sounding body and the effects of source-listener distance. This use of spherical harmonics permits the sounding object to be realistically portrayed without imposing heavy computational loads.

More generally, according to one aspect of the present invention, there is provided a method of sound processing, comprising the step of encoding by spherical harmonics the spatial radiation characteristics of a sounding object.

According to another aspect of the present invention, there is provided a sound processor arranged to encode by spherical harmonics the spatial radiation characteristics of a sounding object.

Said encoding may include generating impulse responses of the sounding object.

Said impulse responses maybe measured or calculated.

A microphone may be spaced from the sounding object and used to measure said impulse responses.

Shape data may be input to represent the shape of the sounding object, from which data said impulse responses are calculated.

Said shape data may be derived from the time of arrival of a first sound at each microphone of an array of microphones placed around the sounding object.

Said shape data maybe synthesised.

The shape of the sounding object maybe traced.

Sound processing methods or sound processors as above may provide for manipulating the spatial characteristics of the sounding object prior to embedding the object in a final soundfield.

Manipulating the spatial characteristics of the sounding object may include transforming the apparent orientation of the sounding object with respect to a listener.

Manipulating the spatial characteristics of the sounding object may include transforming the apparent distance of the sounding object from to a listener.

Sound processing methods or sound processors as above may generate a final impulse response to represent the spatial radiation characteristics of the sounding object and apply said final impulse response to a sound source.

Sound processing methods and sound processors as above may include any one or more of the features disclosed in this specification.

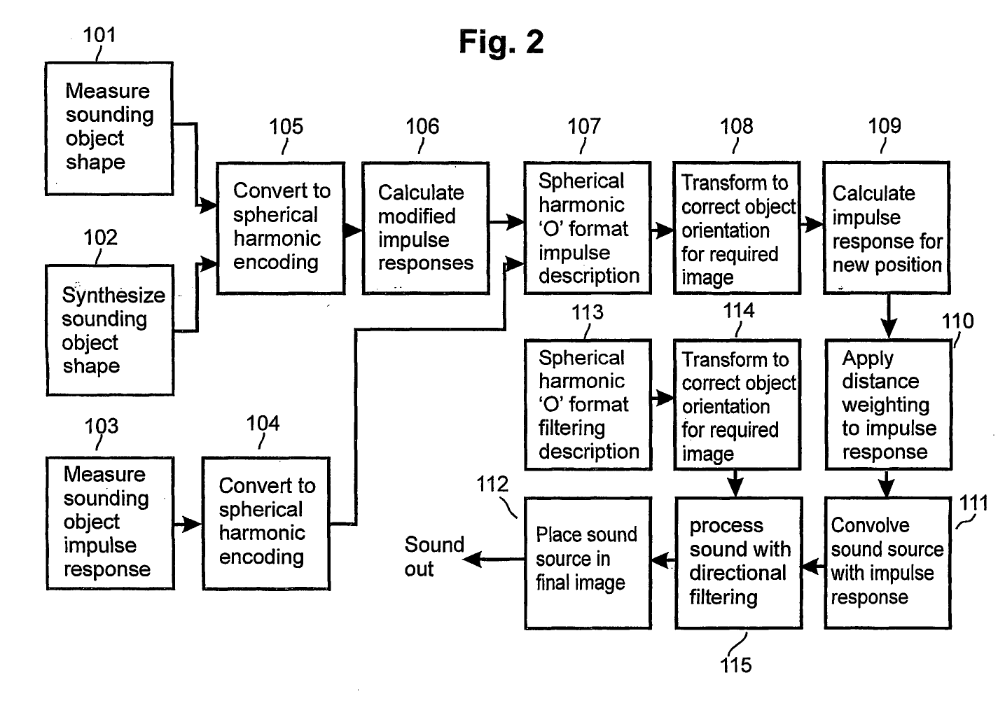

For a better understanding of the invention, and to show how embodiments of the same may be carried into effect, reference will now be made, by way of example, to FIGS. 2 to 6 of the accompanying diagrammatic drawings, in which:

FIG. 2 is a flowchart to illustrate one example of an encoding process in accordance with one example of the invention;

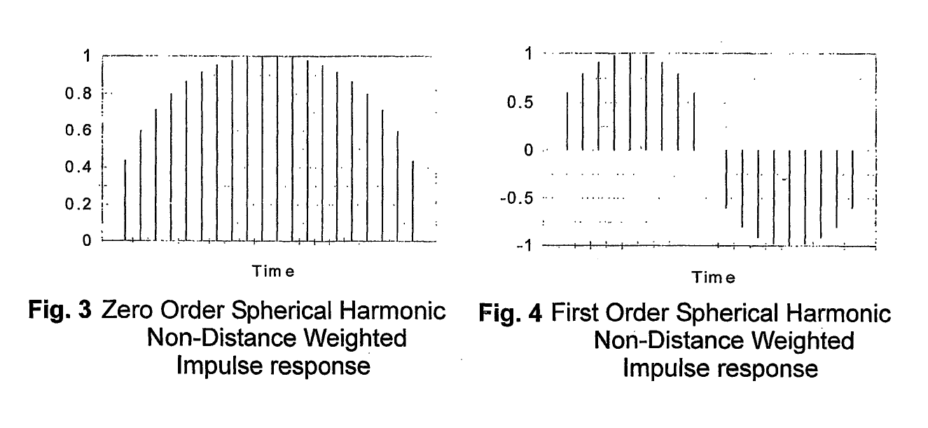

FIG. 3 shows a non-distance weighted impulse response for a zero order spherical harmonic;

FIG. 4 shows a non-distance weighted impulse response for a first order spherical harmonic;

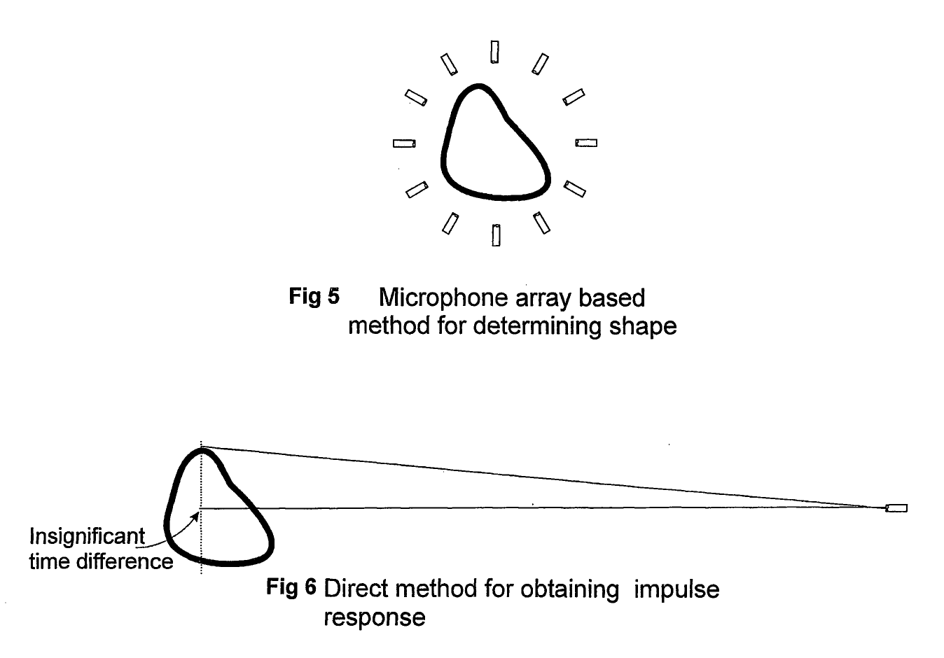

FIG. 5 illustrates an array of microphones for measuring the shape of a sounding object; and

FIG. 6 illustrates use of a microphone, placed far away from a sounding body, to measure an impulse response of correct modified form.

Referring now to FIG. 2, in one example of the invention, the shape of a sounding object is encoded in such a way as to allow easy calculation of the impulse response at the listening point. The shape is decomposed in step 105 into a weighted sum of spherical harmonics, comprising at least the order 0 components and such higher orders as are deemed necessary. The weights are stored individually. The spherical harmonics may take the same names as in ambisonic B format, such that W and X, Y, Z are the order zero harmonic and the three order one harmonics, respectively. Each shape as defined by the individual spherical harmonics is also used to calculate an impulse response for that spherical harmonic, in step 106. These impulse responses are of a modified form where the impulse consists of sums of equally weighted components, so each time point can only take integer values for the size of the impulse at that point. Each point on the shape that has the same delay as another contributes a unit amount to the corresponding time point in the final non-distance weighted impulse response. The length of the impulse response is determined by the overall size of the sounding body. The shape may be synthesised according to the wishes of the user, using any suitable means, such as a Computer Aided Design Package, or by direct input of shape data, as in step 102. Alternatively, the shape of a real object, for instance a piano or an aeroplane, can be traced, as in step 101.

Once the modified impulse responses have been computed, or measured, and transformed into spherical harmonic form in step 107, which we call ‘O’ format, the process allows the apparent orientation and distance of the sounding object to be varied. In step 108, the sounding object is first oriented in the acoustic scene in accordance with its relationship to the listener, for instance by applying rotational transforms such as an angular rotation to the left by an angle of β from the centre front coupled with a tilt by an angle a from the horizontal which requires the following transformation

W′=W

X′=X*cos βY*sin β

Y′=X*sin β*cos a+Y*cos β*cos a−Z*sin a

Z′=X*sin β*sin a+Y*cos β*sin a+Z*cos a

where W′, X′, Y′, Z′ form the rotated and tilted spherical harmonics describing the reoriented sounding object Following this transformation, in step 109, a weighted sum of the spherical harmonic coded impulse responses may be produced, corresponding to the non-distance weighted impulse response required for the relationship of the sounding object to the listening position. The form of these non-distance weighted impulse responses is shown in FIG. 3, which displays the zeroeth spherical harmonic and in FIG. 4, which shows one of the first order spherical harmonics. The effects of distance on the amplitude of each impulse can then be applied in step 110 by weighting the value of the impulse at each time point according to the inverse square law, derived by using the formula

(Ts/Tc)²

where Ts is the tune of appearance of the first component in the impulse response and Tc that of the current component. This produces the final impulse response, the accuracy of whose match to reality can be chosen, in accordance with the computing power available and the quality of effect desired, by varying the number and maximum order of spherical harmonics used.

Following computation of the final impulse response, any sound, recorded or synthesised, may be processed by using the impulse response so generated, via means such as convolution in step 111, so as to apply the appropriate frequency domain corrections such tat it will sound as if it was emitted by the sounding object at the desired distance and orientation from the listening body. Further processing by the already known ambisonic panning processes, or by any other form of sound spatialization, will yield a final image of the desired nature, in step 112.

It will be understood that the surface shape of the object can be determined by normal measurement means and the weighting of the spherical harmonics encoding the shape maybe derived by means of a suitable Fourier series analysis in step 105, yielding the following formulae for the weights of each spherical harmonic component:

$$\begin{matrix}{P}_{mn} = {\int }_{φ = 0}^{π} {\int }_{θ = 0}^{2 π} f ( θ , φ ) {p}_{m m} ( θ , φ ) sin φ ⅆ φ ⅆ θ , 0 \leq m \leq n \\ {Q}_{mn} = {\int }_{φ = 0}^{π} {\int }_{θ = 0}^{2 π} f ( θ , φ ) {q}_{mn} ( θ , φ ) sin φ ⅆ φ ⅆ θ , 1 \leq m \leq n\end{matrix}$$

Since the measurements will, in general be taken on a discrete grid of N points, we may approximate this using a formula such as:

$${\int }_{φ = 0}^{π} {\int }_{θ = 0}^{2 π} f ( θ , φ ) {S}_{m n} ( θ , φ ) sin φ ⅆ φ ⅆ θ \approx {\sum }_{i = 1}^{N} f ( {θ}_{i} , {φ}_{i} ) {S}_{mn} ( {θ}_{i} , {φ}_{i} )$$

Other forms of approximation may be adopted appropriate to the distribution of convenient measurement points. The shape of the sounding object may be measured using an array of microphones such as is illustrated in FIG. 5, where the time of arrival of the first sound at each microphone can be used to determine the distance to the nearest point to that microphone.

FIG. 6 illustrates a further option of this example of the invention, whereby a microphone, if placed far enough away from the sounding body, may be used to measure an impulse response of the correct modified form, as in step 103. This results when the angels subtended by all points on the surface away from the microphone's axis are so small that there is an insignificant extra time difference between points on the microphone axis and those off it. Measurement of a sufficient number of these inpulse responses over an appropriate grid of measurement points enables a spherical harmonic encoded form to be derived in step 104, via a process of approximation similar to that discussed above.

In another option of this exile of the invention, another similar process of spherical harmonic coding can be used to define the distribution of radiation characteristics across the surface of the sphere. This may be accomplished in step 113 by means such as providing different filtering functions to model bright or dull sounding areas of the surface. This is important in, for instance, modelling speech, where the spectral content of the speech varies, depending on whether the person speaking is facing the listener or not. The use of spherical harmonic encoding for the variations of these filtering functions over the surface of the object means that they may be oriented correctly in step 114, in a manner similar to that used for the impulse responses, prior to being applied to the sound instep 115.

In a further option of this example of the invention, the apparent size of the object may be varied by varying the length of the impulse response. This may be accomplished either by recalculating the basic impulse response or otherwise. In one example, this is done by placing the impulse response in a look-up table and using computing means to vary the rate at which values are read out. By either discarding unwanted values when the new impulse response is shorter than the original or, in the case where the new impulse response is longer than the original, by calculating new intermediate values, either by interpolation from adjacent values or otherwise, the length of the impulse response and hence the size of the object can be controlled.

By a similar means, the effect on the impulse response of the distance between the sounding body and the listener being such that the effect of the distance along the Y-axis becomes significant can be incorporated. In this case, the time axis may be warped to model the extra delay imposed by the point's distance from the Y-axis. A typical warping factor is represented by that for the zero order spherical harmonic

{square root over ((sin(cos⁻¹(n)))²+(1−n)²)}

where n is the number of the sample and all points are expressed in terms of multiples of the size of the object. By a similar means, or otherwise, the effect of sound diffusion from areas of the sounding object facing away from the listener or otherwise obstructed from having a direct path to the listening position may be modelled, such that sounds of some wavelengths are delayed more than others, as is well known from the study of acoustics.

The above-described and illustrated examples of the invention enable the construction of more realistic sound objects for use within synthesised ambisonic soundfields, whilst maintaining the simplicity and ease of use of ambisonics.

The above-described and illustrated examples of using spherical harmonics allow sound objects to be manipulated spatially at low computational cost, with processing effects such as rotation, tilt, tumbling, etc., prior to embedding the sound object in a final soundfield. After embedding, only normal manipulations of the soundfield as a whole would normally be possible. The order of the format of the sound object prior to embedding does not have to match that of the soundfield it is eventually embedded in, since it may be passed through a matrix akin to that used for speaker decoding prior to being added, and only the output of the matrix need be of matching order. Tis means that high order descriptions of sound objects can be embedded in standard low order soundfields, allowing very rich acoustic behavior to be implemented without necessarily impacting on the final channel numbers and hence the storage required.

In this specification, the verb “comprise” has its normal dictionary meaning, to denote non-exclusive inclusion. That is, use of the word “comprise” (or any of its derivatives) to include one feature or more, does not exclude the possibility of also including further features.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings), may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A method of sound processing, comprising the step of encoding by spherical harmonics the spatial radiation characteristics of a sounding object.

2. A method according to claim 1, wherein said encoding step includes generating impulse responses of the sounding object.

3. A method according to claim 2, wherein said impulse responses are measured.

4. A method according to claim 3, wherein a microphone is spaced from the sounding object and used to measure said impulse responses.

5. A method according to claim 2, wherein said impulse responses are calculated.

6. A method according to claim 5, including the step of inputting shape data representing the shape of the sounding object, from which data said impulse responses are calculated.

7. A method according to claim 6, including the step of deriving said shape data from the time of arrival of a first sound at each microphone of an array of microphones placed around the sounding object.

8. A method according to claim 6, including the step of synthesising said shape data.

9. A method according to claim 6, including the step of tracing the shape of the sounding object.

10. A method according to any of the preceding claims, including the step of manipulating the spatial characteristics of the sounding object prior to embedding the object in a final soundfield.

11. A method according to claim 10, wherein said step of manipulating the spatial characteristics of the sounding object includes transforming the apparent orientation of the sounding object with respect to a listener.

12. A method according to claim 10 or 11, wherein said step of manipulating the spatial characteristics of the sounding object includes transforming the apparent distance of the sounding object from to a listener.

13. A method according to any of the preceding claims, including the step of generating a final impulse response to represent the spatial radiation characteristics of the sounding object and applying said final impulse response to a sound source.

14. A method of sound processing, the method being substantially as hereinbefore described with reference to the accompanying drawings.

15. A sound processor arranged to encode by spherical harmonics the spatial radiation characteristics of a sounding object.

16. A sound processor according to claim 14 and arranged to carry out a method according to any of claims 1 to 14.

17. A sound processor substantially as hereinbefore described with reference to the accompanying drawings.
